(19) United States
(12) Patent Application Publication
(10) Pub. No.: US 2023/0151228 A1
(43) Pub. Date: May 18, 2023

(54) CONDUCTIVE COMPOSITION AND METHOD FOR PRODUCING SHIELDED PACKAGE USING SAME

(71) Applicant: Tatsuta Electric Wire & Cable Co., Ltd., Osaka (JP)

(72) Inventors: Hiroaki UMEDA, Kizugawa-shi, Kyoto (JP); Hajime NAKAZONO, Kizugawa-shi, Kyoto (JP); Masamichi NISOGI, Kizugawa-shi, Kyoto (JP); Hidetoshi NOGUCHI, Kizugawa-shi, Kyoto (JP); Kazuhiro MATSUDA, Kizugawa-shi, Kyoto (JP)

(21) Appl. No.: 17/916,681

(22) PCT Filed: Jan. 15, 2021
(86) PCT No.: PCT/JP2021/001289

§ 371 Date: Oct. 3, 2022

(30) Foreign Application Priority Data
Apr. 30, 2020 (JP) 2020-080745

(51) Int. Cl. C09D 5/24; C09D 133/10; C09D 133/14; C09D 163/00; C09D 4/06; H01L 23/552; H01L 21/56; H01B 1/22

(52) U.S. Cl. CPC C09D 5/24; C09D 133/10; C09D 133/14; C09D 163/00; C09D 4/06; H01L 23/552; H01L 21/561; H01B 1/22

(57) ABSTRACT

A conductive composition is provided that can be spray coated to form a shielding layer having good shielding capability against 100 MHz to 40 GHz electromagnetic waves, and having desirable adhesion to a package with good laser mark visibility. A method of production of a shielded package with such a conductive composition is also provided. A conductive composition includes at least: (A) a (meth)acrylic resin having a weight average molecular weight of 1,000 or more and 400,000 or less; (B) a monomer having a glycidyl group and/or a (meth)acryloyl group within the molecule; (C) a granular resin component having an average particle diameter of 10 nm to 700 nm; (D) a conductive filler having an average particle diameter of 10 to 500 nm; (E) a scale-like conductive filler having an average particle diameter of 1 to 50 μm; (F) a radical polymerization initiator; and (G) an epoxy resin curing agent, the granular resin component (C) being present in a proportion of 3 to 27 mass % in a resin component containing the acrylic resin (A), the monomer (B), and the granular resin component (C), the conductive filler (D) and the conductive filler (E) being present in an amount of 2,000 to 12,000 parts by mass in total relative to 100 parts by mass of the resin component, the radical polymerization initiator (F) being present in an amount of 0.5 to 40 parts by mass relative to 100 parts by mass of the resin component, and the epoxy resin curing agent (G) being present in an amount of 0.5 to 40 parts by mass relative to 100 parts by mass of the resin component.

### TECHNICAL FIELD

The present invention relates to a conductive composition, and to a method for producing a shielded package using same.

### BACKGROUND ART

In Advanced Driver-Assistance Systems (ADAS) that assist with vehicle operation, the systems accurately perceive, decide, and operate in the same way as humans would behave to realize safe driving. Sensors that use milliwave radar of radio-frequency electromagnetic waves are increasingly used as sensors that provide the perception of a human eye, specifically front and peripheral monitoring sensors. The use of radio-frequency electromagnetic waves is also increasing common in cell phones and tablets in response to the spread of the fifth generation mobile communication system (5G).

The increasing use of radio-frequency electromagnetic waves has raised the risk of malfunctioning in electronic components due to radio-frequency electromagnetic waves. This has created a need for a conductive composition that enables formation of a shielding layer having shielding capability against radio-frequency electromagnetic waves, for example, electromagnetic waves in the 100 MHz to 40 GHz region.

A package is often marked with laser marks such as serial numbers or model numbers on the surface where a conductive composition is applied. This requires forming a shielding layer thin enough to allow such laser marks on a package surface to be read through the shielding layer with a barcode scanner or the like. However, a thinner shielding layer tends to suffer from poor shielding capability, and there is a need for a conductive composition that enables formation of a shielding layer that has shielding capability against radio-frequency electromagnetic waves while providing laser mark visibility.

PTL 1 describes a conductive resin composition that enables a shielding layer having desirable shielding capability against 10 MHz to 1,000 MHz electromagnetic waves to be formed by spray coating, and the shielding layer is described as having desirable adhesion to packages.

However, PTL 1 does not describe satisfying both laser mark visibility and shielding capability against radio-frequency electromagnetic waves higher than 1,000 MHz. The adhesion of the shielding layer to a package also needs further improvement to meet the increasing demand from the market.

### CITATION LIST

### Patent Literature

PTL 1: WO2019/009124

### SUMMARY OF INVENTION

### Technical Problem

The present invention was made under these circumstances, and it is an object of the present invention to provide a conductive composition that enables a shielding layer having desirable shielding capability against 100 MHz to 40 GHz electromagnetic waves to be formed by spray coating, and that can provide desirable adhesion between the shielding layer and a package while providing good laser mark visibility. Another object of the present invention is to provide a shielded package production method with which such a shielding layer can be formed with ease.

### Solution to Problem

A conductive composition of the present invention includes at least: (A) a (meth)acrylic resin having a weight average molecular weight of 1,000 or more and 400,000 or less; (B) a monomer having a glycidyl group and/or a (meth)acryloyl group within the molecule; (C) a granular resin component having an average particle diameter of 10 nm to 700 nm; (D) a conductive filler having an average particle diameter of 10 to 500 nm; (E) a scale-like conductive filler having an average particle diameter of 1 to 50 μm; (F) a radical polymerization initiator; and (G) an epoxy resin curing agent, the granular resin component (C) being present in a proportion of 3 to 27 mass % in a resin component containing the acrylic resin (A), the monomer (B), and the granular resin component (C), the conductive filler (D) and the conductive filler (E) being present in an amount of 2,000 to 12,000 parts by mass in total relative to 100 parts by mass of the resin component, the radical polymerization initiator (F) being present in an amount of 0.5 to 40 parts by mass relative to 100 parts by mass of the resin component, and the epoxy resin curing agent (G) being present in an amount of 0.5 to 40 parts by mass relative to 100 parts by mass of the resin component.

The epoxy resin curing agent (G) may be at least one selected from the group consisting of a phenolic curing agent, an imidazole-based curing agent, an amine-based curing agent, and a cationic curing agent.

The granular resin component (C) may be at least one selected from the group consisting of a polybutadiene rubber, silicone, and a styrene-butylene rubber.

The scale-like conductive filler (E) may have an aspect ratio of 5 to 20.

The monomer (B) may have a glycidyl group and a (meth)acryloyl group within the molecule.

The conductive filler (D) and the conductive filler (E) may have a mass ratio (D):(E) of 5:1 to 1:10.

A shielded package production method of the present invention is a method for producing a shielded package that includes an electronic component mounted on a substrate, and in which the electronic component is sealed with a sealant in the package coated with a shielding layer,

the method including the steps of: mounting a plurality of electronic components on a substrate, and charging and curing a sealant on the substrate to seal the electronic components; cutting the sealant between the electronic components to form grooves, and separating the electronic components into individual packages on the substrate at the grooves; spraying the conductive composition onto surfaces of the separated packages; heating the substrate with the conductive composition applied on the package surfaces so as to cure the conductive composition and form a shielding layer; and cutting the substrate along the grooves to obtain singulated shielded packages.

### Advantageous Effects of Invention

A conductive composition of the present invention enables formation of a coating of a uniform thickness by a spray method, and the coating can protect a package from 100 MHz to 40 GHz electromagnetic waves. By spray coating a package surface with a conductive composition of the present invention, a shielding layer can be formed with ease that shows good adhesion to the package while having excellent shielding capability and laser mark visibility.

According to a shielded package production method of the present invention, a shielded package having excellent shielding capability and good package adhesion can be efficiently produced without using large-scale equipment.

### BRIEF DESCRIPTION OF DRAWINGS

FIG. 1 is a schematic cross sectional view representing an embodiment of a shielded package production method.

FIG. 2 is a plan view showing an example of a shielded package before separation.

FIG. 3 is a schematic cross sectional view of a chip sample used for evaluation of the adhesion of a conductive coating (corner abrasion test).

FIG. 4 is a plan view showing a substrate with a cured product sample used for conductivity evaluation of a conductive coating.

FIG. 5 is a diagram showing a configuration of a system used in a waveguide method.

FIG. 6 is a graph representing the shielding capability against 18 to 26.5 GHz electromagnetic waves.

FIG. 7 is a graph representing the shielding capability against 26.5 to 40 GHz electromagnetic waves.

### DESCRIPTION OF EMBODIMENTS

As set forth above, a conductive composition according to the present invention includes at least: (A) a (meth)acrylic resin having a weight average molecular weight of 1,000 or more and 400,000 or less; (B) a monomer having a glycidyl group and/or a (meth)acryloyl group within the molecule; (C) a granular resin component having an average particle diameter of 10 nm to 700 nm; (D) a conductive filler having an average particle diameter of 10 to 500 nm; (E) a scale-like conductive filler having an average particle diameter of 1 to 50 μm; (F) a radical polymerization initiator; and (G) an epoxy resin curing agent, the granular resin component (C) being present in a proportion of 3 to 27 mass % in a resin component containing the acrylic resin (A), the monomer (B), and the granular resin component (C), the conductive filler (D) and the conductive filler (E) being present in an amount of 2,000 to 12,000 parts by mass in total relative to 100 parts by mass of the resin component, the radical polymerization initiator (F) being present in an amount of 0.5 to 40 parts by mass relative to 100 parts by mass of the resin component, and the epoxy resin curing agent (G) being present in an amount of 0.5 to 40 parts by mass relative to 100 parts by mass of the resin component.

The use of the conductive composition is not particularly limited. However, the conductive composition can preferably be used to obtain a shielded package by forming a shielding layer with the conductive composition sprayed in mist form with a sprayer or the like on a surface of a package before or after singulation.

The (meth)acrylic resin (A) is a polymer containing at least an acrylic acid ester and/or a methacrylic acid ester as constituent monomers. The (meth)acrylic resin (A) is not particularly limited, and may be, for example, a polymer containing at least one constituent monomer selected from the group consisting of methyl acrylate, ethyl acrylate, propyl acrylate, n-butyl acrylate, methyl methacrylate, ethyl methacrylate, propyl methacrylate, and n-butyl methacrylate. The (meth)acrylic resin (A) may contain constituent monomers other than acrylic acid esters or methacrylic acid esters, provided that such monomers are not against the intent and purpose of the present invention. When two or more monomers are contained, the monomers may constitute an alternating copolymer, a random copolymer, a block copolymer, or a graft copolymer. As used herein, “(meth)acrylic resin” is a collective term for “acrylic resin” and “methacrylic resin”.

The (meth)acrylic resin (A) has a weight average molecular weight of 1,000 or more. The preferred weight average molecular weight is 5,000 or more, more preferably 7,000 or more, even more preferably 10,000 or more. The (meth)acrylic resin (A) has a weight average molecular weight of 400,000 or less. The preferred weight average molecular weight is 200,000 or less, more preferably 150,000 or less, even more preferably 50,000 or less. With a weight average molecular weight of 1,000 or more, the conductive composition can more easily have a viscosity suited for spray coating, and provide good dispersibility for the conductive fillers. With a weight average molecular weight of 400,000 or less, the conductivity more easily improves, and provides good shielding capability.

In the present specification, “weight average molecular weight” is a value that can be measured by gel permeation chromatography (GPC), and it is a value calculated with a polystyrene standard curve using tetrahydrofuran as mobile phase.

Examples of the (meth)acrylic resin include copolymers for firing pastes, for example, such as those according to JP-A-2016-155920, JP-A-2015-59196, JP-A-2016-196606, and WO2016/132814. It is also possible to use commercially available acrylic resins, for example, such as KC-1100 and KC-1700P manufactured by Kyoeisha Chemical Co., Ltd.

The content of (meth)acrylic resin (A) is preferably 1 to 70 mass %, more preferably 10 to 65 mass %, even more preferably 15 to 60 mass % of the resin component.

The monomer (B) is a compound having a glycidyl group and/or a (meth)acryloyl group within the molecule, preferably a compound having a glycidyl group and a (meth)acryloyl group within the molecule. In the present specification, “monomer (B)” includes oligomers, and prepolymers having a molecular weight of less than 1,000.

When the monomer (B) has a glycidyl group, the equivalent of a glycidyl group is not particularly limited, and is preferably 100 to 300 g/eq, more preferably 150 to 250 g/eq. When the monomer (B) contains a (meth)acryloyl group, the equivalent of a (meth)acryloyl group is not particularly limited, and is preferably 100 to 300 g/eq, more preferably 150 to 250 g/eq. Here, the equivalents of a glycidyl group and a (meth)acryloyl group are theoretical values. However, in certain cases, the equivalents may be values determined by known methods.

The compound having a glycidyl group is not particularly limited. Examples include glycidyl compounds such as ethyl glycidyl ether, butyl glycidyl ether, t-butyl glycidyl ether, allyl glycidyl ether, benzyl glycidyl ether, glycidyl phenyl ether, bisphenol A, and diglycidyl ether.

The compound having a (meth)acryloyl group is not particularly limited, as long as it is a compound having an acryloyl group or a methacryloyl group. Examples include isoamylacrylate, neopentyl glycol diacrylate, trimethylolpropane triacrylate, ditrimethylolpropane tetraacrylate, 2-hydroxy-3-acryloyloxypropylmethacrylate, ethylene glycol dimethacrylate, and diethylene glycol dimethacrylate.

Examples of the compound having a glycidyl group and a (meth)acryloyl group include acrylic acid glycidyl ether, methacrylic acid glycidyl ether, 4-hydroxybutyl acrylate glycidyl ether, bisphenol A diglycidyl ether acrylic acid adduct, and a phenyl glycidyl ether acrylate hexamethylene diisocyanate urethane prepolymer.

The monomer (B) may be used alone, or two or more monomers (B) may be used in combination. When acrylic resins are used for conductive compositions, poor adhesion tends to occur between the shielding layer and a package after heat curing. However, by using the monomer (B), good adhesion can be provided between the shielding layer and a package even when the conductive filler (D) and the conductive filler (E) are added in large amounts.

The content of monomer (B) is preferably 5 to 80 mass %, more preferably 10 to 50 mass %, even more preferably 15 to 40 mass % of the resin component.

The granular resin component (C) is not particularly limited, as long as it has an average particle diameter of 10 nm to 700 nm. Examples include materials made of, for example, polybutadiene rubber, silicone, or styrene-butylene rubber. In view of increasing dispersibility, the granular resin component (C) may be added to the conductive composition as a masterbatch by being dispersed in a liquid curable resin beforehand. The liquid curable resin is preferably an epoxy resin, specifically, for example, a bisphenol A-type epoxy resin, a bisphenol F-type epoxy resin, a phenol novolac-type epoxy resin, a bisphenol A novolac-type epoxy resin, a brominated epoxy resin, or a glycidyl amine-type epoxy resin. The equivalent of a glycidyl group in the liquid curable resin is not particularly limited, and is preferably 80 to 400 g/eq, more preferably 100 to 300 g/eq. Here, the equivalent of a glycidyl group is a theoretical value. However, in certain cases, the equivalent may be a value determined by known methods.

In the present specification, “average particle diameter” is a number average particle diameter D50 (median size) measured by a laser diffraction scattering method.

The content of granular resin component (C) is not particularly limited, as long as it ranges from 3 to 27 mass % of the resin component. The preferred content is 5 to 16.5 mass %. With 3 mass % or more of granular resin component (C), it is easier to produce good adhesion because the granular resin component (C) dispersed in the conductive composition can absorb stress that generates in the shielding layer as a result of sintering of the conductive fillers during firing. With 27 mass % or less of granular resin component (C), it is easier to provide good shielding capability without impairing conductivity.

When the liquid curable resin is contained, the content of the liquid curable resin is not particularly limited, and is preferably 6 to 55 mass %, more preferably 10 to 35 mass % of the resin component.

The conductive filler (D) having an average particle diameter of 10 to 500 nm is not particularly limited. However, the conductive filler (D) is preferably a copper nanoparticle, a silver nanoparticle, or a gold nanoparticle. With an average particle diameter of 10 to 500 nm, the conductive filler (D) can fill the gaps between the micron-sized conductive fillers, making it easier to add larger amounts of conductive fillers. This makes it easier to improve shielding capability against 100 MHz to 40 GHz electromagnetic waves.

The content of conductive filler (D) is not particularly limited, and is preferably 400 to 10,000 parts by mass, more preferably 2,000 to 7,000 parts by mass, even more preferably 2,200 to 7,000 parts by mass, particularly preferably 2,500 to 6,000 parts by mass relative to 100 parts by mass of the resin component. With 400 parts or more by mass of conductive filler (D), the shielding layer can have desirable conductivity, and it is easier to provide good shielding capability even when the applied thickness is reduced for laser mark visibility. With 10,000 parts or less by mass of conductive filler (D), it is easier to provide good adhesion between the shielding layer and a package, particularly in the corner abrasion test described below, and the conductive composition can more easily show desirable physical properties after curing.

The scale-like conductive filler (E) having an average particle diameter of 1 to 50 μm is not particularly limited, and is preferably a copper powder, a silver powder, a gold powder, a silver-coated copper powder, or a silver-coated copper alloy powder. In view of cost reduction, the scale-like conductive filler (E) is more preferably a copper powder, a silver-coated copper powder, or a silver-coated copper alloy powder. With an average particle diameter of 1 μm or more, the conductive filler (E) can have desirable dispersibility, preventing aggregation or reducing the possibility of oxidation. With an average particle diameter of 50 μm or less, the conductive filler (E) provides desirable connectivity between a package and a ground circuit while providing good laser mark visibility.

The silver-coated copper powder is a copper powder with a silver layer or a silver-containing layer coating at least a part of copper powder particles. The silver-coated copper alloy powder is a copper alloy powder with a silver layer or a silver-containing layer coating at least a part of copper alloy particles. For example, the copper alloy particles have a nickel content of 0.5 to 20 mass %, a zinc content of 1 to 20 mass %, and the balance copper. The balance copper may contain incidental impurities. With such copper alloy particles having a silver-coated layer, a shielded package can be obtained that excels in shielding capability and color fastness.

The scale-like conductive filler (E) has a tapped density of preferably 4.0 to 6.5 g/cm³. With the tapped density confined in this range, the shielding layer can have even more desirable conductivity.

The scale-like conductive filler (E) has an aspect ratio of preferably 5 to 20. With the aspect ratio confined in this range, the shielding layer can have even more desirable conductivity.

The content of conductive filler (E) is not particularly limited, and is preferably 400 to 10,000 parts by mass, more preferably 1,500 to 8,000 parts by mass, even more preferably 2,000 to 7,000 parts by mass, particularly preferably 2,500 to 6,000 parts by mass relative to 100 parts by mass of the resin component. With 400 parts or more by mass of conductive filler (E), the shielding layer can have desirable conductivity, and more easily exhibits good shielding capability against 100 MHz to 40 GHz electromagnetic waves. With 10,000 parts or less by mass of conductive filler (E), it is easier to provide good adhesion between the shielding layer and a package, and the conductive composition can more easily show desirable physical properties after curing. This makes it easier to reduce chipping as might occur in the shielding layer when it is cut with a dicing saw (described later).

The total content of the conductive filler (D) and the conductive filler (E) is 2,000 to 12,000 parts by mass, preferably 3,000 to 12,000 parts by mass, more preferably 5,000 to 11,000 parts by mass, even more preferably 5,500 to 10,000 parts by mass relative to 100 parts by mass of the resin component. With a total content of 2,000 parts or more by mass, it is easier to provide good shielding capability even when the applied thickness is reduced for laser mark visibility. With a total content of 12,000 parts or less by mass, it is easier to provide good adhesion between the shielding layer and a package.

The proportions of conductive filler (D) and conductive filler (E) (conductive filler (D):conductive filler (E)) is not particularly limited, and is preferably 5:1 to 1:10 in terms of a mass ratio.

The radical polymerization initiator (F) is not particularly limited, and may be, for example, a thermal polymerization initiator that initiates radical polymerization by heat, or an energy-ray polymerization initiator that initiates radical polymerization by irradiation of energy rays.

The thermal polymerization initiator is not particularly limited, and conventional organic peroxide compounds and azo compounds can be used as appropriate.

Examples of organic peroxide polymerization initiators include methyl ethyl ketone peroxide, cyclohexanone peroxide, methylcyclohexanone peroxide, methyl acetoacetate peroxide, acetyl acetate peroxide, 1,1-bis(t-hexylperoxy)-3,3,5-trimethylcyclohexane, 1,1-bis(t-hexylperoxy)-cyclohexane, 1,1-bis(t-butylperoxy)-3,3,5-trimethylcyclohexane, 1,1-bis(t-butylperoxy)-2-methylcyclohexane, 1,1-bis(t-butylperoxy)-cyclohexane, 1,1-bis(t-butylperoxy)cyclododecane, t-hexylperoxybenzoate, 2,5-dimethyl-2,5-bis(benzolyperoxy)hexane, t-butyl peroxyallylmonocarbonate, t-butyl trimethylsilyl peroxide, 3,3′,4,4′-tetra(t-butylperoxycarbonyl)benzophenone, and 2,3-dimethyl-2,3-diphenylbutane.

Examples of azo polymerization initiators include 2-phenylazo-4-methoxy-2,4-dimethylvaleronitrile, 1-[(1-cyano-1-methylethyl)azo]formamide, 1,1′-azobis(cyclohexane-1-carbonitrile), 2,2′-azobis(2-methylbutyronitrile), 2,2′-azobisisobutyronitrile, 2,2′-azobis(2,4-dimethylvaleronitrile), 2,2′-azobis(2-methylpropionamidine)dihydrochloride, 2,2′-azobis(2-methyl-N-phenylpropionamidine)dihydrochloride, 2,2′-azobis[N-(4-chlorophenyl)-2-methylpropionamidine]dihydride chloride, 2,2′-azobis[N-(4-hydrophenyl)-2-methylpropionamidine]dihydrochloride, 2,2′-azobis[2-methyl-N-(phenylmethyl)propionamidine]dihydrochloride, and dimethyl 2,2′-azobis(isobutyrate).

The thermal polymerization initiator may be used alone, or two or more thermal polymerization initiators may be used in combination.

The content of radical polymerization initiator (F) is 0.5 to 40 parts by mass, preferably 2 to 30 parts by mass, more preferably 5 to 20 parts by mass relative to 100 parts by mass of the resin component. With the content of radical polymerization initiator confined in these ranges, curing of the conductive composition can sufficiently take place. This provides good adhesion between the shielding layer and a package surface, and the shielding layer can have desirable conductivity, making it easier to provide good shielding capability to the shielding layer. Changing the type and amount of radical polymerization initiator allows the composition to be used for different purposes, such as in applications requiring a shorter cure time, or applications requiring long-term storage stability at room temperature.

The epoxy resin curing agent (G) is not particularly limited, and may be, for example, a phenolic curing agent, an imidazole-based curing agent, an amine-based curing agent, or a cationic curing agent. These may be used alone, or two or more epoxy resin curing agents may be used in combination.

Examples of the phenolic curing agent include novolac phenol, and naphthol compounds.

Examples of the imidazole-based curing agent include imidazole, 2-undecyl imidazole, 2-heptadecyl imidazole, 2-methyl imidazole, 2-ethyl imidazole, 2-phenyl imidazole, 1-benzyl-2-phenyl imidazole, 2-ethyl-4-methyl-imidazole, and 1-cyanoethyl-2-undecyl imidazole.

Examples of the cationic curing agent include amine salts of boron trifluoride, and onium compounds such as P-methoxybenzenediazonium hexafluorophosphate, diphenyliodonium hexafluorophosphate, triphenylsulfonium, tetra-n-butylphosphonium tetraphenylborate, and tetra-n-butylphosphonium-o,o-diethylphosphorothioate.

The content of epoxy resin curing agent (G) is 0.5 to 40 parts by mass, preferably 1 to 20 parts by mass, more preferably 2 to 15 parts by mass relative to 100 parts by mass of the resin component. With 0.5 parts or more by mass of curing agent, desirable adhesion can be provided between the shielding layer and a package surface, and the shielding layer can have desirable conductivity, making it easier to provide good shielding capability to the shielding layer. With 40 parts or less by mass of curing agent, it is easier to obtain a conductive composition having good storage stability.

A conductive composition of the present invention may contain known additives, for example, such as a defoaming agent, a thickener, an adhesive agent, a filler, a fire retardant, and a colorant, provided that addition of such additives does not hinder the intent and purpose of the invention.

Preferably, a conductive composition of the present invention has a lower viscosity than what is commonly called a conductive paste, in order to allow the conductive composition to be evenly applied to a package surface by spraying.

The viscosity and use of a conductive composition of the present invention is preferably adjusted as appropriate according to the device used for application, and is not particularly limited. However, the information given below can be used as a general guideline. The method of viscosity measurement is not limited either. For a low-viscosity conductive composition, a cone-and-plate rotational viscometer (or a cone-plate viscometer as it is also called) may be used for viscosity measurement, whereas a single cylindrical rotational viscometer (or a B-type or BH-type viscometer as it is commonly called) may be used for the viscosity measurement of a high-viscosity conductive composition.

When a cone-and-plate rotational viscometer is used for measurement, it is preferable that the viscosity measured with a Cone Spindle CP40 (cone angle: 0.8°, cone radius: 24 mm; manufactured by BROOK FIELD) at 10 rpm be 10 mPa·s or more, more preferably 30 mPa·s or more. When the viscosity is 10 mPa·s or more, the liquid can be prevented from dripping when the applied surface is not horizontal, enabling uniform formation of a conductive coating. When the viscosity is around 10 mPa·s or lower, it is effective, in order to obtain a uniform coating of the desired thickness, to apply the composition multiple times by repeating the formation of a thin film using a reduced amount of composition for each application. Here, there is no problem with the composition having a higher viscosity, provided that the viscosity is in the measurable range of a cone-and-plate rotational viscometer.

When a single cylindrical rotational viscometer is used for measurement, it is preferable that the viscosity measured with a No. 2 rotor at 10 rpm be 10 dPa·s or less, more preferably 5 dPa·s or less. When the viscosity is 10 dPa·s or less, it is easier to prevent clogging of a spray nozzle, and to form a uniform conductive coating. Here, there is no problem with the composition having a lower viscosity, provided that the viscosity is in the measurable range of a single cylindrical rotational viscometer.

The viscosity of the conductive composition depends on factors such as the viscosity of the resin component, and the content of the conductive fillers. Accordingly, a solvent can be used to bring the viscosity of the conductive composition to the foregoing ranges. The solvent that can be used in the present invention is not particularly limited, and may be, for example, propylene glycol monomethyl ether, 3-methoxy-3-methyl-1-butanol, 3-methoxy-3-methyl-1-butyl acetate, acetone, methyl ethyl ketone, acetophenone, methyl cellosolve, methyl cellosolve acetate, Methyl Carbitol, diethylene glycol dimethyl ether, tetrahydrofuran, methyl acetate, or butyl acetate. These may be used alone, or two or more solvents may be used in combination.

Preferably, the solvent content is appropriately adjusted according to factors such as the use of the conductive composition, and the device used for application. Accordingly, the solvent content varies with conditions such as the viscosity of the resin component, and the content of the conductive fillers. As a reference, the solvent content is about 10 to 60 mass % relative to the total amount of the components (except for the solvent) contained in the conductive composition.

A shielding layer obtained by using a conductive composition of the present invention has good adhesion to a ground circuit formed of a copper foil or the like. Specifically, because of the desirable adhesion between the shielding layer and the copper foil of ground circuit partially exposed on a shielded package, detachment of the shielding layer from the ground circuit due to the impact of cutting can be prevented when the package is cut and singulated after forming the shielding layer by applying the conductive composition to a surface of the shielded package.

From the viewpoint of achieving good shielding capability against 100 MHz to 40 GHz electromagnetic waves, a coating formed of a conductive composition of the present invention has a resistivity of preferably 5.0×10⁻⁵ Ω·cm or less when used as a shielding layer.

The following describes an embodiment of a method for obtaining a shielded package with a conductive composition of the present invention, with reference to the accompanying drawings.

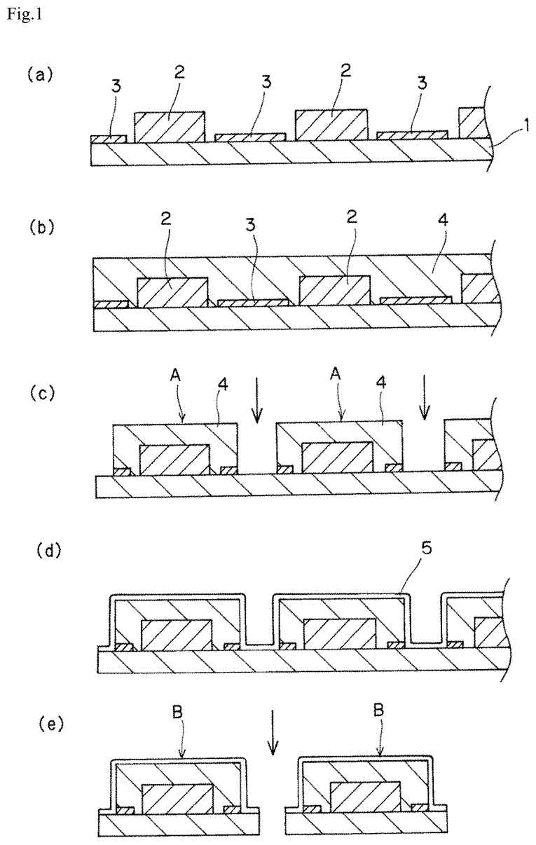

As shown in FIG. 1(a), a substrate 1 is prepared that includes a plurality of electronic components (e.g., ICs) 2 mounted thereon, and a ground circuit pattern (copper foil) 3 provided between the electronic components 2.

As shown in FIG. 1(b), a sealant 4 is charged and cured on the electronic components 2 and the ground circuit pattern 3 to seal the electronic components 2.

The sealant 4 is cut between the electronic components 2 to form grooves, as indicated by arrows in FIG. 1(c), and the electronic components are separated into individual packages on the substrate 1 at the grooves. Each separated package is indicated by symbol A. The ground circuit is at least partially exposed at the wall surfaces forming the grooves, and the grooves do not fully penetrate the substrate at the bottom.

Separately, a conductive composition is prepared by mixing the resin component, the conductive fillers, and the curing agent in predetermined amounts, together with an optional solvent.

The conductive composition is evenly applied over the package surface by spraying it in mist form with a known spray gun or the like. Here, the pressure and flow rate of the spray, and the distance between the orifice of the spray gun and the package surface are appropriately set as needed.

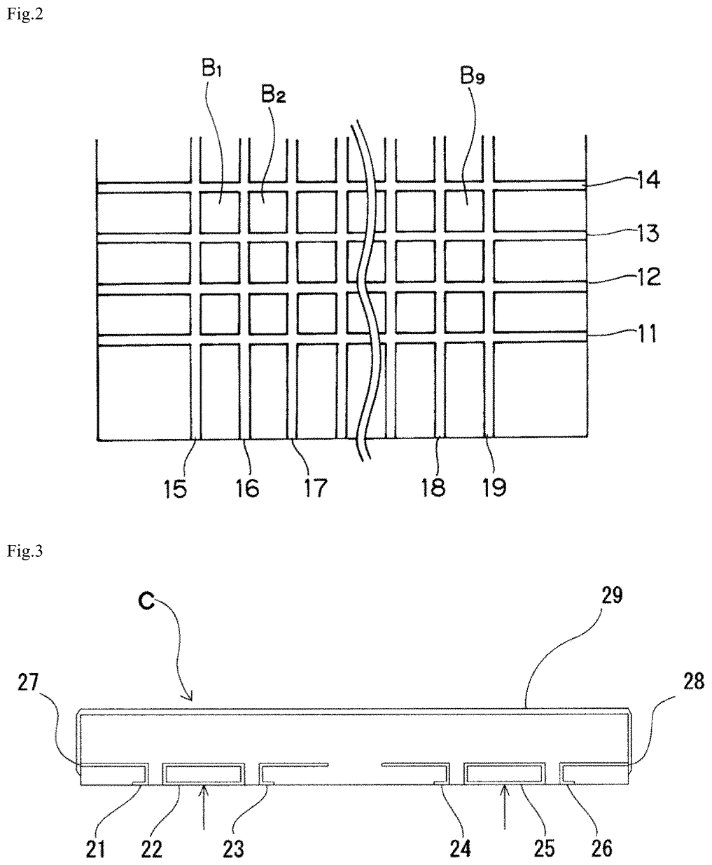

After the application of the conductive composition, the package with the conductive composition is heated to thoroughly dry the solvent, followed by heating to sufficiently cure the conductive composition. This forms a shielding layer (conductive coating) 5 on the package surface, as shown in FIG. 1(d). Here, the heating conditions can be set as appropriate. FIG. 2 is a plan view showing the substrate in this state. The shielded packages before singulation are indicated by symbols B₁ to B₉. The grooves between the shielded packages are indicated by symbols 11 to 19.

Thereafter, the substrate is cut with a dicing saw or the like along the bottom of the grooves of the packages before singulation, as indicated by arrow in FIG. 1(e). This results in singulated packages B.

The singulated packages B have desirable shielding capability because each package B has a shielding layer evenly formed on its surfaces (the top surface, the side surfaces, and the corners where the top surface meets the side surfaces). Because the shielding layer has good adhesion to the package surface and to the ground circuit, the shielding layer can be prevented from being detached from the package surface or ground circuit by the impact of package singulation with a dicing saw or the like.

### Examples

The following describes the substance of the present invention in greater detail using Examples. However, the present invention is not limited to the following. In the following, “part(s)” and “%” are by mass, unless otherwise specifically stated.

### Examples and Comparative Examples

A conductive composition was obtained by adding and mixing conductive fillers, a radical polymerization initiator, an epoxy resin curing agent, and a solvent in the proportions shown in Tables 1 and 2, relative to total 100 parts by mass of the (meth)acrylic resin, monomer, and masterbatch below. Details of the components used are as follows.

(Meth)acrylic resin 1: molecular weight=17,000

(Meth)acrylic resin 2: molecular weight=100,000, KC-1700P manufactured by Kyoeisha Chemical Co., Ltd.

(Meth)acrylic resin 3: molecular weight=130,000, KC-1100 manufactured by Kyoeisha Chemical Co., Ltd.

Monomer 1: 4-hydroxybutylacrylate glycidyl ether

Masterbatch 1: A masterbatch containing a granular resin component (formed of polybutadiene rubber, average particle diameter=100 nm) dispersed in a bisphenol A-type epoxy resin. The content of granular resin component is 30 mass %.

Masterbatch 2: A masterbatch containing a granular resin component (formed of silicone, average particle diameter=100 nm) dispersed in a bisphenol F-type epoxy resin. The content of granular resin component is 25 mass %.

Conductive filler 1: silver particle (average particle diameter=150 nm)

Conductive filler 2: silver-coated copper alloy powder (average particle diameter=5 μm, flake-like, aspect ratio=2 to 10, tapped density=5.8 g/cm³)

Conductive filler 3: silver-coated copper alloy powder (average particle diameter=70 μm, flake-like, aspect ratio=2 to 10, tapped density=5.5 g/cm³)

Radical polymerization initiator: dimethyl 2,2′-azobis(isobutyrate)

Epoxy resin curing agent: 2E4MZ (2-ethyl-4-methylimidazole), manufactured by Shikoku Chemicals Corporation

Solvent: Methyl Ethyl Ketone (MEK)

The conductive compositions of Examples and Comparative Examples were evaluated as follows. The results are presented in Tables 1 and 2.

Laser Mark Visibility

Laser marks (data matrix code: 17 characters) were applied on a molded resin using a green femto processing machine LodeStone manufactured by ESI, under the laser marking conditions below. The conductive composition was then spray coated on the molded resin with a spraying machine (SL-940E, manufactured by Nordson Asymtek) under the spraying conditions below. After spray coating, the composition was cured by being heated at 100° C. for 10 minutes, and at 150° C. for 50 minutes to form a coated film having a thickness of 6 μm. The coated film was then tested to determine whether the laser marks applied on the molded resin were readable through the coated film, using a barcode scanner Xenon 1902 (manufactured by Honeywell, attachment: AR-01) in the settings below. The composition was determined as having good laser mark visibility (Good) when the laser marks were readable, and poor laser mark visibility (Poor) when the laser marks were unreadable.

### Laser Marking Conditions

Laser pattern: dots
Laser mark depth: 40 μm at maximum
Laser mark diameter: 40 μm
Laser mark interval: 10 μm
Offset value of laser focusing along Z axis: 0.0 mm
Power: 0.3 W
Laser pulse pitch: 1.89 μm
Irradiation rate: 188.5 mm/s
Frequency: 100 KHz
Cycles: 2

### Spraying Conditions

Main air: 1.0 psi
Assisting air: 6 psi
Head speed: 400 mm/s
Nozzle size: 30 G
Temperature of target surface: 25° C.
Distance from target surface to nozzle: about 1.5 cm

### Settings of Barcode Scanner

Aiming (alignment function): off
Print weight: 1 or 2
Read target: data matrix

### Conductivity (Resistivity) of Conductive Coating

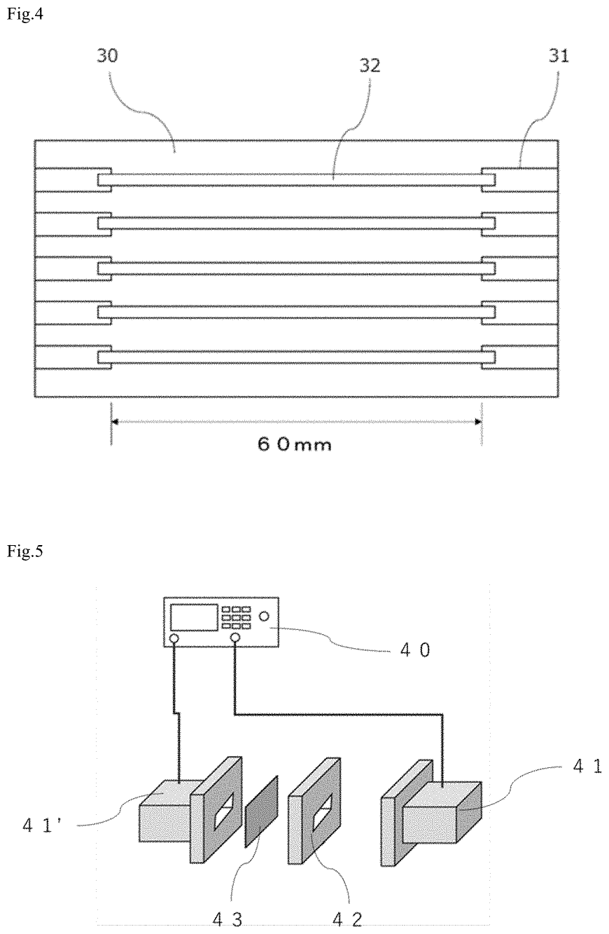

The conductivity of the conductive coating obtained with the conductive composition of Example 1 was evaluated in terms of a resistivity. Specifically, as shown in FIG. 4, a 55 μm-thick polyimide film with 5 mm-wide slits was attached to a glass epoxy substrate 30 on which copper-foil electrode pads 31 had been provided at the both ends, 60 mm apart from each other. Here, the film was attached to mask the substrate with the end portions of the slits overlying the electrode pads 31 at the ends of the substrate. The conductive composition obtained in each Example and Comparative Example was then spray coated with a spraying machine (SL-940E, manufactured by Nordson Asymtek) under the following spraying conditions.

### Spraying Conditions

Main air: 2.8 psi
Assisting air: 5 psi
Spray head pitch: 3.0 mm
head speed: 450 mm/s
Nozzle size: 30 G
Temperature of target surface: 25° C.
Distance from target surface to nozzle: about 1.5 cm

The whole was heated at 100° C. for 10 minutes, and at 150° C. for 60 minutes to cure the composition, and the polyimide film was detached to obtain a substrate 30 having a cured product 32 (70 mm in length, 5 mm in width, about 6 μm in thickness) joining the electrode pads 31 at the ends of the substrate. The cured product sample was then measured for a resistance value (Q) between the electrode pads, using a tester, and a resistivity (Ω·cm) was calculated from cross sectional area S (cm²) and length L (cm), using the following formula (1).

$$\begin{matrix}[ Math . 1 ] & \\ Resistivity = \frac{S}{L} \times R & ( 1 )\end{matrix}$$

The cross sectional area, length, and resistivity of the sample was determined as mean values from a total of 15 cured product samples (five each for three glass epoxy substrates). The shielding capability is desirable, and the cured product can be suitably used as a shielding layer when the resistivity is 5×10⁻⁵ Ω·cm or less.

The resistivity was measured in the same fashion for the other Examples and Comparative Examples.

### Adhesion of Conductive Composition (Corner Abrasion Test)

A chip sample C (1.0 cm×1.0 cm, 1.3 mm thick) formed of a glass epoxy substrate (FR-5) and molded resin was used as an IC package model. As shown in FIG. 3, the chip sample C had circuits 21 to 26 formed as an internal layer by through-hole plating with a 35 μm-thick copper foil. The circuits 21, 22, and 23 are a part of a continuous circuit. The circuits 24, 25, and 26 are a part of another continuous circuit. The circuits 21 to 23 and the circuits 24 to 26 are not connected to each other. The circuits 22 and 25 have pad portions where the copper foil is partially exposed at the bottom of the chip sample, as indicated by arrows. The circuits 21 and 26 have circuit end portions 27 and 28, respectively, that are exposed at the end surfaces of the chip sample.

The conductive composition was sprayed to the surface of the chip sample C under the spraying conditions below, and was cured by being heated at 100° C. for 10 minutes, and at 150° C. for 50 minutes to form a shielding layer (conductive coating) 29 having a thickness of about 6 μm.

### Spraying Conditions

Main air: 2.8 psi
Assisting air: 5 psi
Spray head pitch: 3.0 mm
Head speed: 450 mm/s
Nozzle size: 30 G
Temperature of target surface: 25° C.
Distance from target surface to nozzle: about 1.5 cm

A Clean Nolle nitrile glove, manufactured by As One Corporation, was placed over a metal spatula 0.5 mm thick and 15 mm wide, and a corner of the chip sample C was rubbed back and forth three times under 700 g pressure to see if the conductive coating becomes detached. The adhesion was determined as being superior (Good) when there was no detachment, and inferior (poor) when detachment was observed in any part of the rubbed coating.

### Adhesion of Conductive Composition (Comparison Before and After Solder Dipping)

The adhesion of the shielding layer to a package surface or a ground circuit was determined according to JIS K 5600-5-6: 1999 (Cross-Cut Test).

Specifically, a copper-clad laminate was prepared for the evaluation of adhesion to a ground circuit, and a molded resin was prepared for the evaluation of adhesion to a package surface. Each was masked with a polyimide tape with an opening measuring 5 cm in width and 10 cm in length, and the conductive composition was sprayed with a spray coating machine SL-940E (manufactured by Nordson Asymtek) under the spraying conditions below. The whole was then heated at 150° C. for 60 minutes to cure the composition, and the polyimide tape was removed to obtain a coating having a thickness of about 6 μm. The coated copper foil and the coated molded resin were subjected to a cross-cut test. The cross-cut test was conducted before reflow and after a reflow process, which was performed 3 times with a maximum temperature of 260° C., 10 seconds each time.

### Spraying Conditions

Main air: 2.8 psi
Assisting air: 5 psi
Spray head pitch: 3.0 mm
Head speed: 450 mm/s
Nozzle size: 30 G
Temperature of target surface: 25° C.
Distance from target surface to nozzle: about 1.5 cm

The adhesion was evaluated using the following criteria. The composition was determined as having good adhesion when it had a score of 0 or 1.

0: The edges of the cuts are completely smooth; no detachment in any of the squares in the grid

1: Small flakes of coating have detached at intersections of the cuts. A cross-cut area of less than 5% is clearly affected.

2: The coating has detached along edges and/or intersections of the cuts. A cross-cut area of more than 5% is clearly affected but the area affected does not exceed 15%.

3: The coating has partially or completely flaked in large strips along the edges of the cuts, and/or some squares have partially or completely detached. A cross-cut area of more than 15% is clearly affected but the area affected does not exceed 35%.

4: The coating has partially or completely flaked in large strips along the edges of the cuts, and/or several squares have partially or completely detached. Less than 35% of the cross-cut area is clearly affected.

5: A degree of flaking that cannot fall within classification 4.

The conductive composition of Example 1 was evaluated for its shielding capability against 18 to 40 GHz electromagnetic waves, using the system shown in FIG. 5. Specifically, the conductive composition was sprayed onto an about 25 μm-thick polyimide film with a spraying machine SL-940E (manufactured by Nordson Asymtek) under the spraying conditions below. The whole was then heated at 100° C. for 10 minutes, and at 150° C. for 50 minutes to cure the composition, and form a coating having a thickness of about 6 μm. The coating was then cut in the shape of a measurement probe to prepare a measurement sample 43.

### Spraying Conditions

Main air: 2.8 psi
Assisting air: 5 psi
Spray head pitch: 3.0 mm
Head speed: 450 mm/s
Nozzle size: 30 G
Temperature of target surface: 25° C.
Distance from target surface to nozzle: about 1.5 cm

The measurement sample 43 was subjected to ten runs of waveguide measurement under the conditions below, and a mean value of measured attenuation levels was used to evaluate shielding capability.

### Measurement Conditions

Data point: 201
Intermediate frequency: 100 Hz

The system shown in FIG. 5 is configured from an electromagnetic wave shielding effect measurement device 40, coaxial waveguide adaptors 41 and 41′ for sending and receiving electromagnetic waves, and a sample holder 42 for securing a measurement sample.

The following devices were used to send 18 to 26.5 GHz electromagnetic waves.

Electromagnetic wave shielding effect measurement device 40: Network Analyzer E8361A, manufactured by Keysight Technologies

Coaxial waveguide adaptors 41 and 41′: K-281C, manufactured by Keysight Technologies

Sample holder 42: Sample holder WR-42, 3 mm thick, manufactured by EM labs. Inc.

The following devices were used to send 26.5 to 40 GHz electromagnetic waves.

Electromagnetic wave shielding effect measurement device 40: Network Analyzer E8361A, manufactured by Keysight Technologies

Coaxial waveguide adaptors 41 and 41′: R-281A, manufactured by Keysight Technologies

Sample holder 42: Sample holder WR-28, 3 mm thick, manufactured by EM labs. Inc.

The coaxial waveguide adaptors 41 and 41′ were disposed face to face, and the sample holder 42, securing the measurement sample 43, was disposed between the coaxial waveguide adaptors 41 and 41′.

In the waveguide method, an output signal from the electromagnetic wave shielding effect measurement device 40 is sent to the sending coaxial waveguide adaptor 41, and the electromagnetic wave shielding effect measurement device 40 measures the level of the signal received by the receiving coaxial waveguide adaptor 41′. The electromagnetic wave shielding effect measurement device 40 outputs an attenuation level when the measurement sample 43 is installed in the sample holder 42, relative to the state where the measurement sample 43 is not installed in the sample holder 42.

The sample was determined as having a good shielding effect when the attenuation level was 80 dB or higher.

TABLE 1

| | | Example | | | | | | | | | | | | |
|---|---|---|---|---|---|---|---|---|---|---|---|---|---|---|
| | | 1 | 2 | 3 | 4 | 5 | 6 | 7 | 8 | 9 | 10 | 11 | 12 | 13 |
| (Meth)acrylic resin 1 | | 56 | 1 | 66 | 56 | 50 | 37 | — | — | 56 | 1 | 56 | 56 | 56 |
| (Meth)acrylic resin 2 | | — | — | — | — | — | — | — | 37 | — | — | — | — | — |
| (Meth)acrylic resin 3 | | — | — | — | — | — | — | 37 | — | — | — | — | — | — |
| Monomer 1 | | 22 | 77 | 12 | 22 | 28 | 41 | 41 | 41 | 22 | 22 | 22 | 22 | 22 |
| Masterbatch 1 | | 22 | 22 | 22 | 22 | 22 | 22 | 22 | 22 | — | 77 | 22 | 22 | 22 |
| Masterbatch 2 | | — | — | — | — | — | — | — | — | 22 | — | — | — | — |
| Conductive filler 1 | | 2700 | 600 | 3200 | 2700 | 2500 | 2500 | 2700 | 2700 | 2700 | 1000 | 2700 | 2700 | 3000 |
| Conductive filler 2 | | 3800 | 1430 | 3800 | 3800 | 500 | 2500 | 3800 | 3800 | 3800 | 1300 | 3800 | 3800 | 7000 |
| Radical polymerization | | 5 | 5 | 5 | 0.5 | 5 | 5 | 5 | 5 | 5 | 5 | 35 | 5 | 5 |
| initiator | | | | | | | | | | | | | | |
| Epoxy resin curing agent | | 3 | 3 | 3 | 0.5 | 3 | 3 | 3 | 3 | 3 | 3 | 3 | 30 | 3 |
| Solvent | | 1625 | 508 | 1750 | 1625 | 750 | 1250 | 1625 | 1625 | 1625 | 575 | 1625 | 1625 | 2500 |
| Content of granular resin | | 7.26 | 7.26 | 7.26 | 7.26 | 7.26 | 7.26 | 7.26 | 7.26 | 5.5 | 25.41 | 7.26 | 7.26 | 7.26 |
| component | | | | | | | | | | | | | | |
| Laser mark visibility | | Good | Good | Good | Good | Good | Good | Good | Good | Good | Good | Good | Good | Good |
| Resistivity | | 2.50 | 4.5 | 2.30 | 3.90 | 3.30 | 3.0 | 3.80 | 2.70 | 2.60 | 4.90 | 2.40 | 4.10 | 1.50 |
| (×10⁻⁵ Ω · cm) | | | | | | | | | | | | | | |
| Comer abrasion test | | Good | Good | Good | Good | Good | Good | Good | Good | Good | Good | Good | Good | Good |
| Cross-cut | Before | 0 | 0 | 0 | 0 | 0 | 0 | 0 | 0 | 0 | 0 | 0 | 0 | 0 |
| test | solder | | | | | | | | | | | | | |
| | dipping | | | | | | | | | | | | | |
| | After reflow | 0 | 0 | 0 | 0 | 0 | 0 | 0 | 0 | 0 | 0 | 0 | 0 | 1 |

TABLE 2

| | | Comparative Example | | | | |
|---|---|---|---|---|---|---|
| | | 1 | 2 | 3 | 4 | 5 |
| (Meth)acrylic resin 1 | | 78 | 75 | 10 | 56 | 56 |
| Monomer 1 | | 22 | 22 | 5 | 22 | 22 |
| Masterbatch 1 | | — | 3 | 85 | 22 | 22 |
| Conductive filler 1 | | 2700 | 2700 | 2700 | 2700 | 2700 |
| Conductive filler 2 | | 3800 | 3800 | 3800 | 3800 | — |
| Conductive filler 3 | | — | — | — | — | 3800 |
| Radical polymerization | | 5 | 5 | 5 | 5 | 5 |
| initiator | | | | | | |
| Epoxy resin curing agent | | — | 3 | 3 | 0.2 | 3 |
| Solvent | | 1625 | 1625 | 1625 | 1625 | 1625 |
| Content of granular resin | | — | 0.99 | 28.05 | 7.26 | 7.26 |
| component | | | | | | |
| Laser mark visibility | | Good | Good | Good | Good | Poor |
| Resistivity | | 2.0 | 3.3 | 6.3 | 2.1 | Poor |
| (×10⁻⁵ Ω · cm) | | | | | | |
| Comer abrasion test | | Poor | Poor | Good | Poor | Good |
| Cross-cut | Before | 0 | 0 | 0 | 0 | 0 |
| test | solder | | | | | |
| | dipping | | | | | |
| | After reflow | 0 | 0 | 0 | 0 | 0 |

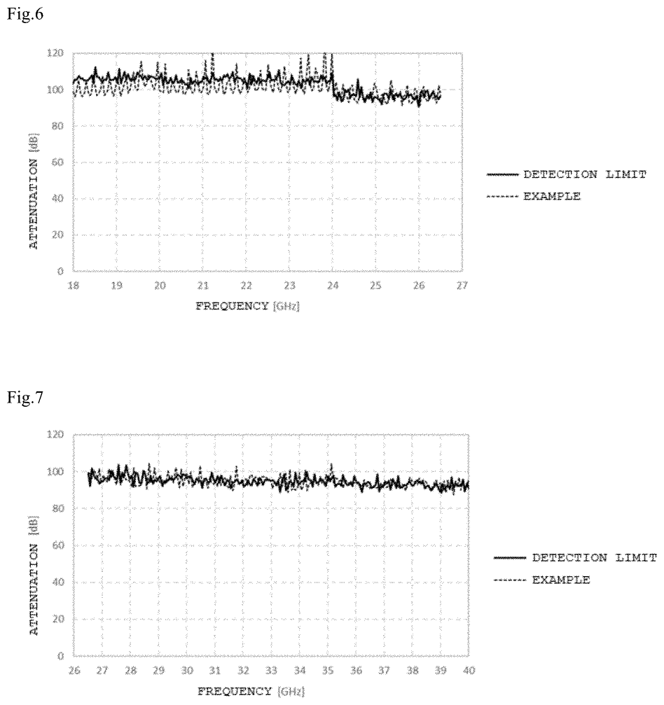

The results presented in Table 1 confirmed that the coatings obtained with the conductive compositions of Examples all had desirable conductivity. As shown in FIGS. 6 and 7, these coatings had an attenuation level of 80 dB or higher, confirming that the coatings have good shielding capability against 18 to 40 GHz electromagnetic waves. Because transmission decreases with decreasing frequency of electromagnetic waves, it can be said that a coating also has good shielding capability against electromagnetic waves shorter than 18 GHz when it has good shielding capability against electromagnetic waves of 18 GHz and higher. Accordingly, the coatings of Examples were determined as having good shielding capability against electromagnetic waves of the 100 MHz to 40 GHz range. The results were also desirable for the adhesion between the shielding layer and the package surface or the ground circuit, and for laser mark visibility.

As shown in Table 2, the results of corner abrasion test were not desirable in Comparative Example 1 (corresponding to the conductive resin composition of PTL 1), which did not contain a granular resin component, and in Comparative Example 2, in which the content of granular resin component was below the lower limit.

The resistivity was high, and the desired shielding capability was not obtained in Comparative Example 3, in which the content of granular resin component was above the upper limit.

The result of corner abrasion test was undesirable in Comparative Example 4, in which the content of epoxy resin curing agent was below the lower limit.

It was not possible to form a uniform conductive coating in Comparative Example 5, in which the conductive filler with an average particle diameter of 1 to 50 μm did not have a scale-like shape.

### REFERENCE SIGNS LIST

A: Package separated on substrate
B: Singulated shielded package
B1, B2, B9: Shielded package before singulation
C: Chip sample
1: Substrate
2: Electronic component
3: Ground circuit pattern (copper foil)
4: Sealant
5: Shielding layer (conductive coating)
11 to 19: Groove
21 to 26: Circuit
27, 28: Circuit end portion
29: Shielding layer (conductive coating)
30: Substrate
31: Electrode pad
32: Cured product of conductive composition
40: Electromagnetic wave shielding effect measurement device
41, 41′: Coaxial waveguide adaptor
42: Sample holder
43: Measurement sample

1. A conductive composition comprising at least:
(A) a (meth)acrylic resin having a weight average molecular weight of 1,000 or more and 400,000 or less;
(B) a monomer having a glycidyl group and/or a (meth)acryloyl group within the molecule;
(C) a granular resin component having an average particle diameter of 10 nm to 700 nm;
(D) a conductive filler having an average particle diameter of 10 to 500 nm;
(E) a scale-like conductive filler having an average particle diameter of 1 to 50 μm;
(F) a radical polymerization initiator; and
(G) an epoxy resin curing agent,
the granular resin component (C) being present in a proportion of 3 to 27 mass % in a resin component containing the acrylic resin (A), the monomer (B), and the granular resin component (C),
the conductive filler (D) and the conductive filler (E) being present in an amount of 2,000 to 12,000 parts by mass in total relative to 100 parts by mass of the resin component,
the radical polymerization initiator (F) being present in an amount of 0.5 to 40 parts by mass relative to 100 parts by mass of the resin component, and
the epoxy resin curing agent (G) being present in an amount of 0.5 to 40 parts by mass relative to 100 parts by mass of the resin component.

2. The conductive composition according to claim 1, wherein the epoxy resin curing agent (G) is at least one selected from the group consisting of a phenolic curing agent, an imidazole-based curing agent, an amine-based curing agent, and a cationic curing agent.

3. The conductive composition according to claim 1, wherein the granular resin component (C) is at least one selected from the group consisting of a polybutadiene rubber, silicone, and a styrene-butylene rubber.

4. The conductive composition according to claim 1, wherein the scale-like conductive filler (E) has an aspect ratio of 5 to 20.

5. The conductive composition according to claim 1, wherein the monomer (B) has a glycidyl group and a (meth)acryloyl group within the molecule.

6. The conductive composition according to claim 1, wherein the conductive filler (D) and the conductive filler (E) have a mass ratio (D):(E) of 5:1 to 1:10.

7. A shielded package production method for producing a shielded package that includes an electronic component mounted on a substrate, and in which the electronic component is sealed with a sealant in the package coated with a shielding layer,
the method comprising the steps of:
mounting a plurality of electronic components on a substrate, and charging and curing a sealant on the substrate to seal the electronic components;
cutting the sealant between the electronic components to form grooves, and separating the electronic components into individual packages on the substrate at the grooves;
spraying the conductive composition of claim 1 onto surfaces of the separated packages;
heating the substrate with the conductive composition applied on the package surfaces so as to cure the conductive composition and form a shielding layer; and
cutting the substrate along the grooves to obtain singulated shielded packages.

8. The conductive composition according to claim 2, wherein the granular resin component (C) is at least one selected from the group consisting of a polybutadiene rubber, silicone, and a styrene-butylene rubber.

9. The conductive composition according to claim 2, wherein the scale-like conductive filler (E) has an aspect ratio of 5 to 20.

10. The conductive composition according to claim 3, wherein the scale-like conductive filler (E) has an aspect ratio of 5 to 20.

11. The conductive composition according to claim 8, wherein the scale-like conductive filler (E) has an aspect ratio of 5 to 20.

12. The conductive composition according to claim 2, wherein the monomer (B) has a glycidyl group and a (meth)acryloyl group within the molecule.

13. The conductive composition according to claim 3, wherein the monomer (B) has a glycidyl group and a (meth)acryloyl group within the molecule.

14. The conductive composition according to claim 8, wherein the monomer (B) has a glycidyl group and a (meth)acryloyl group within the molecule.

15. The conductive composition according to claim 2, wherein the conductive filler (D) and the conductive filler (E) have a mass ratio (D):(E) of 5:1 to 1:10.

16. The conductive composition according to claim 3, wherein the conductive filler (D) and the conductive filler (E) have a mass ratio (D):(E) of 5:1 to 1:10.

17. The conductive composition according to claim 8, wherein the conductive filler (D) and the conductive filler (E) have a mass ratio (D):(E) of 5:1 to 1:10.

18. A shielded package production method for producing a shielded package that includes an electronic component mounted on a substrate, and in which the electronic component is sealed with a sealant in the package coated with a shielding layer,
the method comprising the steps of:
mounting a plurality of electronic components on a substrate, and charging and curing a sealant on the substrate to seal the electronic components;
cutting the sealant between the electronic components to form grooves, and separating the electronic components into individual packages on the substrate at the grooves;
spraying the conductive composition of claim 2 onto surfaces of the separated packages;
heating the substrate with the conductive composition applied on the package surfaces so as to cure the conductive composition and form a shielding layer; and
cutting the substrate along the grooves to obtain singulated shielded packages.

19. A shielded package production method for producing a shielded package that includes an electronic component mounted on a substrate, and in which the electronic component is sealed with a sealant in the package coated with a shielding layer,
the method comprising the steps of:
mounting a plurality of electronic components on a substrate, and charging and curing a sealant on the substrate to seal the electronic components;
cutting the sealant between the electronic components to form grooves, and separating the electronic components into individual packages on the substrate at the grooves;
spraying the conductive composition of claim 3 onto surfaces of the separated packages;
heating the substrate with the conductive composition applied on the package surfaces so as to cure the conductive composition and form a shielding layer; and
cutting the substrate along the grooves to obtain singulated shielded packages.

20. A shielded package production method for producing a shielded package that includes an electronic component mounted on a substrate, and in which the electronic component is sealed with a sealant in the package coated with a shielding layer,
the method comprising the steps of:
mounting a plurality of electronic components on a substrate, and charging and curing a sealant on the substrate to seal the electronic components;
cutting the sealant between the electronic components to form grooves, and separating the electronic components into individual packages on the substrate at the grooves;
spraying the conductive composition of claim 8 onto surfaces of the separated packages;
heating the substrate with the conductive composition applied on the package surfaces so as to cure the conductive composition and form a shielding layer; and
cutting the substrate along the grooves to obtain singulated shielded packages.
